(19) United States
(12) Patent Application Publication
(10) Pub. No.: US 2025/0362324 A1
(43) Pub. Date: Nov. 27, 2025

(54) TERMINAL CONFIGURATIONS OF PXIe DIGITAL MULTIMETER AND ADAPTER

(71) Applicant: Keysight Technologies, Inc., Santa Rosa, CA (US)

(72) Inventors: Masaki Sato, Tokyo (JP); Tomotaka Hosotani, Tokyo (JP); Yukiya Toyama, Tokyo (JP); Yuki Shimizu, Tokyo (JP)

(21) Appl. No.: 18/669,920

(22) Filed: May 21, 2024

(51) Int. Cl. G01R 15/12

(52) U.S. Cl. CPC G01R 15/125

(57) ABSTRACT

A digital multimeter device (DMM) has a PXIe form factor and includes a front panel including three triaxial terminals aligned along a length of the front panel, a fuse holder accessible from the front panel, and trigger input and output terminals located on the front panel. Each of the three triaxial terminals may include a center core wire, an inner conductor surrounding the center core wire, and an outer conductor. A chassis ground may be assigned to the outer conductor of each of the three triaxial terminals. A high (HI) terminal, a high sense (HIS) terminal, and a current (I) terminal may be respectively assigned to the center core wires of the three triaxial terminals.

### FIELD

The present disclosure generally relates to digital multimeters, and more specifically, to the configuration and arrangement of terminals on the front panel of a PXIe digital multimeter device. The present disclosure also relates to an adaptor for converting the front panel terminal configuration of a PXIe digital multimeter device.

### BACKGROUND

Digital multimeters (DMMs) are versatile instruments used in a variety of fields, including electronics, automotive, aerospace, and industrial applications, for measuring electrical parameters such as voltage, current, and resistance. These devices are designed to provide accurate and reliable measurements, making them an indispensable tool in any electrical engineer's toolkit.

DMMs come in various form factors, including benchtop, handheld, and modular designs. Among these, the PXIe (PCI extensions for Instrumentation Express) form factor has gained popularity due to its compact size and high performance. PXIe is a rugged PC-based platform for measurement and automation systems, combining PCI electrical-bus features with the modular, Eurocard packaging of CompactPCI, and then adding specialized synchronization buses and software features.

In a typical DMM, several measurement functions are provided, including DC voltage (DCV), AC voltage (ACV), DC current (DCI), AC current (ACI), and resistance measurements. These measurements are usually performed through a set of input terminals on the device. The configuration and arrangement of these terminals can greatly affect the ease of use and functionality of the DMM.

In many DMMs, the terminals are divided for each measurement function to ensure a designed withstand voltage and performance isolation between the terminals, and to reduce the frequency of changing the connections between the DMM and the device under test (DUT). However, this can lead to a large number of terminals, which can be difficult to accommodate on a compact device such as a PXIe DMM.

Furthermore, in addition to the measurement terminals, DMMs often include other features such as trigger input and output terminals, and a fuse holder. These additional features can further complicate the terminal configuration and require additional space on the device.

### SUMMARY

According to an aspect of the inventive concepts, a digital multimeter device (DMM) is provided having a PXIe form factor and including a front panel including three triaxial terminals aligned along a length of the front panel, a fuse holder accessible from the front panel, and trigger input and output terminals located on the front panel.

Each of the three triaxial terminals may include a center core wire, an inner conductor surrounding the center core wire, and an outer conductor.

A chassis ground may be assigned to the outer conductor of each of the three triaxial terminals.

A high (HI) terminal, a high sense (HIS) terminal, and a current (I) terminal may be respectively assigned to the center core wires of the three triaxial terminals.

The three triaxial terminals may include an upper triaxial terminal, a lower triaxial terminal, and a middle triaxial terminal located between the upper and lower triaxial terminals, and a low (LO) terminal may be assigned to the inner conductor of each upper and lower triaxial terminals. A low sense (LOS) terminal may be assigned to the inner conductor of the middle triaxial terminal.

The inner conductors of the upper and lower triaxial terminals may be electrically connected inside the device.

The DMM may further include a triaxial-to-banana adapter having a back panel configured for attachment to the three triaxial terminals and a front panel having five banana terminals. The adaptor may be configured such that the trigger input and output terminals are accessible on the front panel when the triaxial-to-banana adapter is attached to the three triaxial terminals.

According to another aspect of the inventive concepts, a digital multimeter device (DMM) is provided that includes a front panel including an upper triaxial terminal, a middle triaxial terminal, and a lower triaxial terminal, each triaxial terminal including a center core wire, an inner conductor surrounding the center core wire, and an outer conductor assigned as a chassis ground terminal. The center core wires of the upper, middle and lower triaxial terminals respectively constitute a high (HI) terminal, a high sense (HIS) terminal, and a current (I) terminal. The inner conductors of the upper, middle and lower triaxial terminals respectively constitute a low (LO) terminal, a low sense (LOS) terminal, another LO terminal. The LO terminal of the upper triaxial terminal and the other LO terminal of the lower triaxial terminal are connected together within the device.

The DMM may have a PXIe form factor.

The front panel may be 105 mm in length, and 20 mm in width.

The DMM may further include trigger input and output terminals located on the front panel.

The DMM may further include a fuse holder accessible from the front panel.

The DMM may further comprise a triaxial-to-banana adapter having a back panel configured for attachment to the upper, middle and lower triaxial terminals, and a front panel having five banana terminals.

According to still another aspect of the inventive concepts, an adaptor is provided that is configured to convert a front panel configuration of a PXIe form factor digital multimeter (DMM) device having less than five input terminals. The adapter includes a back panel including rear terminals configured to connect to the corresponding input terminals of the DMM, a front panel having five separate input terminals, and an adaptor housing electrically connecting each of the input terminals of the front panel to a respective one of the rear terminals of the back panel.

The rear terminals of the back panel may include three triaxial terminals.

Each of the three triaxial terminals of the back panel may include a center core wire, an inner conductor surrounding the center core wire, and an outer conductor.

The three triaxial terminals of the back panel may include an upper triaxial terminal, a middle triaxial terminal, and a lower triaxial terminal. The center core wires of the upper, middle and lower triaxial terminals may respectively constitute a high (HI) DMM terminal, a high sense (HIS) DMM terminal, and a current (I) DMM terminal, and inner conductors of the upper, middle and lower triaxial terminals may respectively constitute a low (LO) DMM terminal, a low sense (LOS) DMM terminal, another DMM LO terminal.

The five separate terminals on the front panel may includes an HI adaptor terminal electrically connected to the HI DMM terminal, an LO adaptor terminal electrically connect to the LO DMM terminal, an I adaptor terminal electrically connected to the I DMM terminal, an HIS adaptor terminal electrically connected to the HIS DMM terminal, and an LOS adaptor terminal electrically connect to the LOS DMM terminal.

Each of the HI adaptor terminal, the LO adaptor terminal, the I adaptor terminal, the HIS adaptor terminal, and the LOS adaptor terminal may be configured as a banana terminal.

### BRIEF DESCRIPTION OF FIGURES

The above and other aspects and features of the inventive concepts will become readily apparent from the detailed description that follows, with reference to the accompanying drawings, in which:

FIG. 1 illustrates an example of a conventional digital multimeter (DMM) module having a VXI form factor;

FIG. 2 illustrates an example of a conventional DMM module having a PXI form factor;

FIG. 3 illustrates a front panel layout of another conventional DMM module having a PXIe form factor;

FIGS. 4 and 5 are circuit diagrams for reference in describing the impact of a DMM having four input terminals instead of five input terminals;

FIG. 6 illustrates a front panel of a DMM module according to embodiments of the inventive concepts;

FIG. 7 illustrates a side view of an adaptor module according to embodiments of the inventive concepts; and

FIG. 8 illustrates the adaptor module of FIG. 7 operatively coupled with the DMM module of FIG. 6 according to embodiments of the inventive concepts.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted to avoid obscuring the description of the example embodiments. Such methods and apparatuses are clearly within the scope of the present teachings. Further, throughout the drawings, like reference numbers refer to the same or similar elements.

Conventionally, measurements made with a digital multimeter (DMM) are voltage measurements, resistance measurements, and current measurements. In the case of resistance measurements, there are 2-terminal measurements and 4-terminal measurements. To enable all these measurements using a single DMM module or instrument, five Banana terminals are generally defined and installed as input terminals on the front panel of the DMM. These five terminals are designated as a HI (high input) terminal, a LO (low input) terminal, an I (current input) terminal, a HIS (high input sense) terminal, and a LOS (low input sense) terminal. For a voltage measurement, the voltage between HI and LO is measured by the DMM. For a current measurement, current input to the I terminal is measured by the DMM while the LO terminal is used as a current return terminal. For a 2-terminal resistance measurement, a resistor under test is connected between HI and LO. For 4-terminal resistance measurement, a resistor under test is connected to the HI and HIS terminals on one side of the resistor, and to the LO and LOS terminals on the other side. All of the measurements are carried out internally of the DMM using electronic circuitry that is well known in the art.

Design considerations in the placement of the various terminals include ensuring that there is an adequate withstand voltage between terminals, and ensuring that there is adequate performance isolation between terminals. Separately, the provision of dedicated terminals may reduce the number of times connection set-ups between the DMM and device under test (DUT) need to be changed.

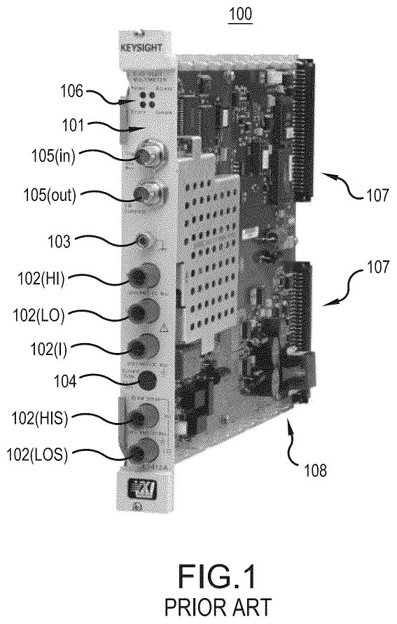

In the meantime, in some cases the DMM is configured as a module for insertion into the slot of a multi-slot chassis or rack. Here, the size, shape and other physical attributes of the DMM module are set by industry standards known as form factors. On such form factor is the VXI form factor, and example of which is shown in FIG. 1 described next.

FIG. 1 shows the front panel 101 and internal components 108 of a VXI form factor DMM 100. Here, the front panel is 20 mm wide and 230 mm high. These relatively large front panel dimensions allow for the provision of five banana terminals spaced sufficiently apart to ensure sufficient withstand voltages and performance isolation between terminals. In FIG. 1, the banana terminals are referenced by the terminal designations as 102(HI), 102(LO), 102(I), 102(HIS) and 102(LOS). In addition, the VXI front panel 101 is large enough to also accommodate other elements, such as a trigger input terminal 105(in), a trigger output terminal 105(out), a ground port 103, a fuse holder 104, and indicator lights 106. Reference number 107 of the figure denotes connectors for connection of the DMM 100 to counterpart connectors of the chassis (not shown).

Another known form factor is the PXI/PXIe form factor module mentioned earlier. The primary advantage of the PXI/PXIe (simply PXIe hereinafter) form factor is that it is more compact than the VXI form factor.

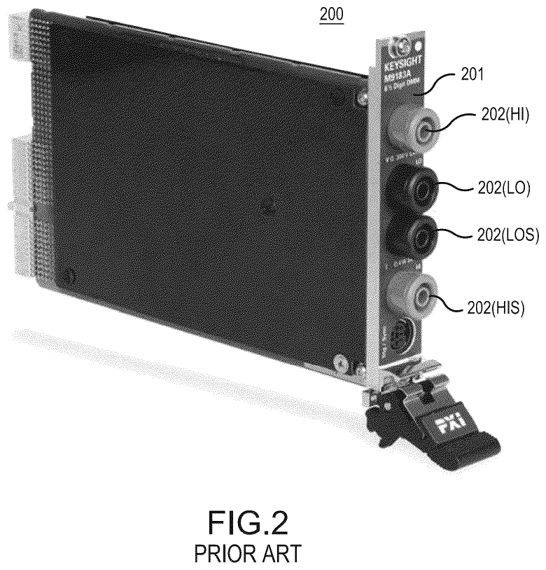

FIG. 2 illustrates an example of a PXI form factor DMM module 200. Namely, the “M9183A” DMM manufactured by Keysight Technologies is shown. Here, the front panel 201 is 20 mm wide and 105 mm high. Due to its relatively small size, only four banana terminals can be made available on the front panel while still maintaining adequate spacing between terminals. These terminals are designated as 202(HI), 202(LO), 202(LOS) and 202(HIS) in the figure. Since there are only four available terminals, two of the terminals must be shared. In the case of the M9183A, the 202(HIS) and 202(LOS) terminals for four-terminal measurements are shared with the I and LO terminals for current measurement, respectively. This requires equipping the DMM module with internal circuitry that allows the user to switch the inputs to the appropriate internal circuitry depending on the measurement being carried out.

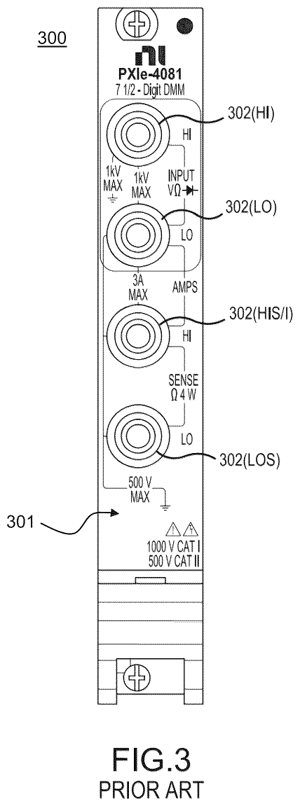

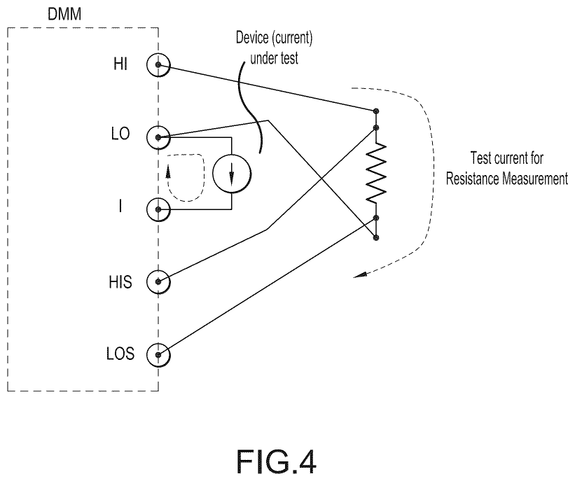

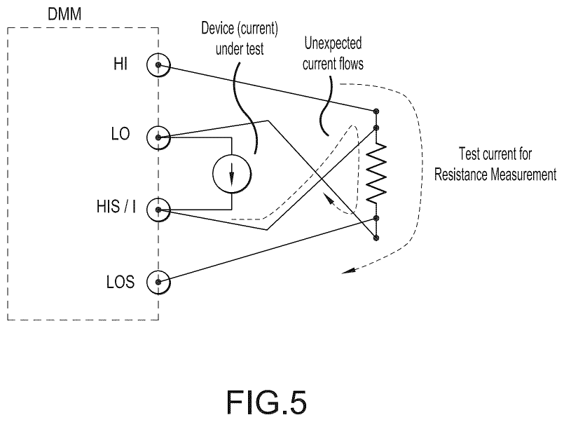

FIG. 3 depicts the front panel layout of another example of a PXIe form factor DMM module 300. In this case, the “PXIe-4081 DMM” offered by National Instruments is shown. As with the M9183A DMM, the PXIe-4081 DMM includes a PXIe form factor panel 301 having four banana terminals 302. In the example of this DMM, the HIS and I terminals are shared. In the figure, the four banana terminals are designated as 302(HI), 302(LO), 302(HIS/I) and 302(LOS). As such, the user needs to change the connection configuration between the device under test and the DMM for 4-wire resistance measurements and current measurements. This is explained further in connection with FIGS. 4 and 5 discussed next.

Consider first the example of FIG. 4 where five separate HI, LO, I, HIS and LOS terminals are available. The illustrated connections show a current test of a device under test (DUT) connected across the LO and I terminals. In addition, a 4-terminal resistance measurement is set up with a resistance connected at one end to the HI and HIS terminals, and at another end to the LO and LOS terminals. As represented by the two dashed-arrow in the figure, the currents of these two measurements do not interfere with each other.

On the other hand, consider the case where the HIS and I terminals are shared as shown in FIG. 5. In the case of 4-terminal resistance measurement, the DMM supplies current from the HI terminal. It flows through the resistor and returns to the LO terminal. In addition, the high side of the resistor is connected to the HIS terminal and the low side to the LOS terminal in order to measure the voltage between the HIS and LOS terminals to measure the resistance. Here, if a current source that the user wants to measure after the 4-terminal resistance measurement is connected to the I terminal, that is shared with the HIS terminal, this current will also flow to the resistance that is currently being measured. Therefore, to perform accurate four-terminal measurements, it is necessary remove the connection of the current source from the terminals.

The present disclosure relates to digital multimeter devices, particularly those designed for use in automated test equipment. In some aspects, the digital multimeter device may include a front panel configured to accommodate a plurality of triaxial terminals, each assigned to a specific measurement function. This arrangement may allow for a compact design while maintaining the ability to perform a variety of measurement functions without the inconvenience of altering connections between measurements.

A digital multimeter (DMM) according to embodiments of the inventive concepts will now be described.

Initially, it is noted that an example of DMM in accordance with embodiments of the inventive concepts is the “M1412A” 7.5 Digit PXIe Digital Multimeter offered by Keysight Technologies. The M1412A is described in a publication entitled “M1412A 7.5 Digit PXIe Digital Multimeter—User Guide, Edition 1”, published by Keysight Technologies in April 2024, the disclosure of which is incorporated by reference herein in its entirety.

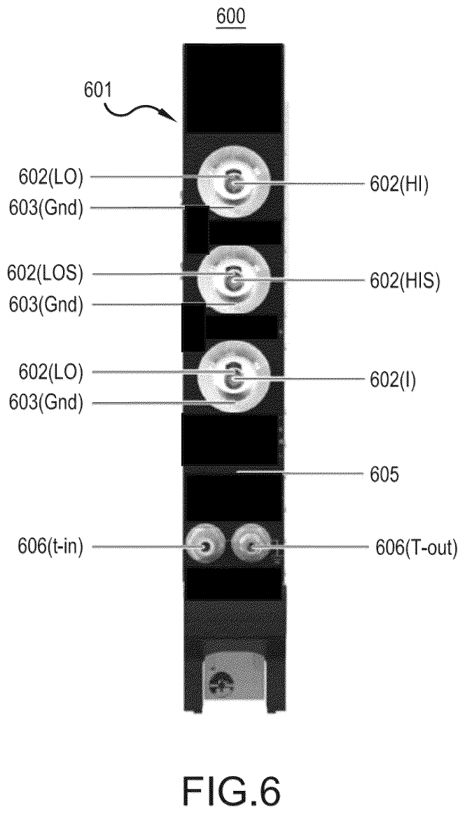

FIG. 6 illustrates a front panel 601 of a DMM module 600 according to embodiments of the inventive concepts. The DMM 600 may have a PXIe form factor.

As shown, the front panel 601 of this embodiment is equipped with three triaxial terminals (described below) aligned along a length of the front panel. In addition, a fuse holder 605 is accessible from the front panel, and a trigger input terminal 606(T-in) and a trigger output terminal 606(T-out) are located on the front panel.

Each of the three triaxial terminals comprises a center core wire, an inner conductor surrounding the center core wire, and an outer conductor. In the example of FIG. 6, a chassis ground is assigned to the outer conductor 603(Gnd) of each of the three triaxial terminals. Also in the example of FIG. 6, high (HI) terminal, a high sense (HIS) terminal, and a current (I) terminal are respectively assigned to the center core wires 602(HI), 602(HIS) and 602(I) of the three triaxial terminals. And finally, in the example of FIG. 6, a low (LO) terminal is assigned to the inner conductor 602(LO) of each upper and lower triaxial terminals, and a low sense (LOS) terminal is assigned to the inner conductor 602(LOS) of the middle triaxial terminal. Here, the inner conductors 602(LO) of the upper and lower triaxial terminals are electrically connected inside the device.

As mentioned above, the DMM 600 may have a PXIe form factor. In this case, the front panel is about 105 mm in length, and about 20 mm in width.

One aspect to note with respect to the PXIe form factor embodiment of FIG. 6 is that sharing of terminals (as with the previously described M9183A and PXIe-4081) is not necessary. Further, since the terminals required for DMM measurements are consolidated into three triaxial terminals, access to the fuse holder and trigger input and output terminals is available on front panel. That is, in order to ensure a sufficient withstand voltage between each terminal, it is necessary to have a specified creepage distance between the terminal conductors to comply with industry safety standard such those dictated by IEC61010. In previous PXIe form factor implementations in which four banana terminals are arranged on the front panel, there is a tradeoff between withstand voltage rating and the provision of trigger input/output terminals. For example, the PXIe-4081 does not have trigger terminals, whereas the M9183A has front panel trigger input/output pins. However, the banana pins of the M9183A are closer together, and thus the withstand voltage rating of the M9183A is lower than that of the PXIe-4081. In addition, neither the M9183A nor the PXIe-4081 has front panel access to the fuse holder, and as a result, the DMM module must be removed from the chassis to replace the fuse.

In embodiments of the inventive concept, each DMM terminal is separate and independent from the others, and the provisioning of triaxial terminals allows for sufficient withstand voltages between terminals. For example, each triaxial terminal may be a withstand voltage of 300V DC and 300V AC between the inner conductor and the center core wire. As such, for example, the withstand voltage between HI and LO may be 300V DC and 300V AC. Further, since separate HI, HIS, I, LO and LOS terminals are made available, it is not necessary to share terminals and/or change the test set-up as described previously. Still further, as mentioned above, the front panel has adequate room for the fuse holder and trigger input/output terminals as well.

Separately, in some embodiments of the inventive concepts, the potential of the outer shield of each triaxial terminal is designated as a chassis ground. As such, noise disturbances in the conductors surrounded by the outer shields may be mitigated. This may be especially advantageous when measuring relatively small voltages and currents. That is, for example, the chassis ground may be used in this way to protect the HI-LO, HIS-LOS, or I-LO signals.

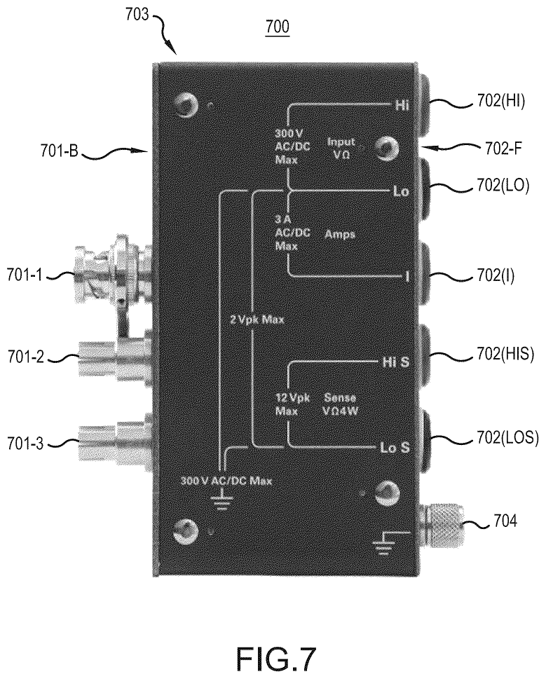

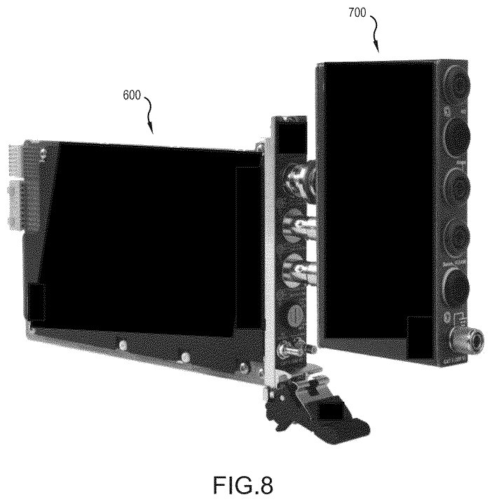

FIG. 7 illustrates a side view of an adaptor module according to embodiments of the inventive concepts, and FIG. 8 illustrates the adaptor module of FIG. 7 operatively coupled with the DMM module of FIG. 6 according to embodiments of the inventive concepts.

Referring collectively to FIGS. 7 and 8, the adaptor module 600 is configured to convert a front panel configuration of a PXIe form factor digital multimeter (DMM) device 700. In the illustrated example, the DMM device is the DMM module 600 of FIG. 6, but the inventive concepts are not limited in this manner. That is, the DMM can be another device having a different terminal configuration than that of FIG. 6.

The adaptor module 700 includes back panel 701-B, a front panel 702-F and an adaptor housing 703 between the back and read panels 701-B and 702-F. The back panel 701-B includes rear terminals configured to connect to the corresponding input terminals of the DMM. In the example of FIG. 7, the rear terminals are rear triaxial terminals 701-1, 701-2 and 701-3 configured for connection to the triaxial terminals of the DMM module of FIG. 6. The front panel 702-F is equipped with five separate input terminals. In the illustrated example, these five separate input terminals are designated as 702(HI), 702(LO), 702(I), 702(HIS) and 702(LOS). The adaptor housing 703 electrically connects each of the input terminals of the front panel 702-F to a corresponding one of the rear terminals of the back panel 701-B.

In the example where the DMM module is the DMM module of FIG. 6, the center core wires of the upper, middle and lower triaxial terminals 701-1, 701-2 and 701-3 may respectively constitute a high (HI) DMM terminal, a high sense (HIS) DMM terminal, and a current (I) DMM terminal, and the inner conductors of the upper, middle and lower triaxial terminals 701-1, 701-2 and 701-3 may respectively constitute a low (LO) DMM terminal, a low sense (LOS) DMM terminal, another DMM LO terminal. In the case, the HI adaptor terminal 702(HI) is electrically connected to the HI DMM terminal, the LO adaptor terminal 702(LO) is electrically connected to the LO DMM terminal, the I adaptor terminal 702(I) is electrically connected to the I DMM terminal, the HIS adaptor terminal 702(HIS) is electrically connected to the HIS DMM terminal, and the LOS adaptor terminal 702(LOS) is electrically connected to the LOS DMM terminal.

In example embodiments, each of the terminals on the front panel 702-F are banana terminals. However, the inventive concepts are not limited to banana terminals on the front panel, and instead other types of terminal connections may be equipped.

The adaptor module 700 allows the user to convert, for example, the triaxial terminals of the DMM module 600 into conventional banana terminals. This may desired in the case where the user prefers to use conventional banana terminal connections to the device(s) under test.

As is best shown in FIG. 8, the adaptor module 700 may be configured such that the trigger input and output terminals of the DMM module 600 are accessible on the front panel when the adaptor module 700 is attached to the three triaxial terminals of the DMM module 600.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from study of the drawings, the disclosure, and the appended claims. While representative embodiments are disclosed herein, one of ordinary skill in the art will appreciate that many variations that are in accordance with the present teachings are possible and remain within the scope of the appended claim set. The invention therefore is not to be restricted except within the scope of the appended claims.

What is claimed is:

1. A digital multimeter device (DMM) having a PXIe form factor and comprising:
a front panel including three triaxial terminals aligned along a length of the front panel;
a fuse holder accessible from the front panel; and
trigger input and output terminals located on the front panel.

2. The DMM of claim 1, wherein each of the three triaxial terminals comprises a center core wire, an inner conductor surrounding the center core wire, and an outer conductor.

3. The DMM of claim 2, wherein a chassis ground is assigned to the outer conductor of each of the three triaxial terminals.

4. The DMM of claim 2, wherein a high (HI) terminal, a high sense (HIS) terminal, and a current (I) terminal are respectively assigned to the center core wires of the three triaxial terminals.

5. The DMM of claim 4, wherein the three triaxial terminals include an upper triaxial terminal, a lower triaxial terminal, and a middle triaxial terminal located between the upper and lower triaxial terminals, and
wherein a low (LO) terminal is assigned to the inner conductor of each upper and lower triaxial terminals, and
wherein a low sense (LOS) terminal is assigned to the inner conductor of the middle triaxial terminal.

6. The DMM of claim 5, wherein the inner conductors of the upper and lower triaxial terminals are electrically connected inside the device.

7. The DMM of claim 1, further comprising a triaxial-to-banana adapter having a back panel configured for attachment to the three triaxial terminals and a front panel having five banana terminals.

8. The DMM of claim 7, wherein the adaptor is configured such that the trigger input and output terminals are accessible on the front panel when the triaxial-to-banana adapter is attached to the three triaxial terminals.

9. A digital multimeter device (DMM), comprising:
a front panel including an upper triaxial terminal, a middle triaxial terminal, and a lower triaxial terminal, each triaxial terminal including a center core wire, an inner conductor surrounding the center core wire, and an outer conductor assigned as a chassis ground terminal,
wherein center core wires of the upper, middle and lower triaxial terminals respectively constitute a high (HI) terminal, a high sense (HIS) terminal, and a current (I) terminal, and
wherein inner conductors of the upper, middle and lower triaxial terminals respectively constitute a low (LO) terminal, a low sense (LOS) terminal, another LO terminal,
wherein the LO terminal of the upper triaxial terminal and the other LO terminal of the lower triaxial terminal are connected together within the device.

10. The DMM of claim 9, wherein the DMM has a PXIe form factor.

11. The DMM of claim 9, wherein the front panel is 105 mm in length, and 20 mm in width.

12. The DMM of claim 9, further comprising trigger input and output terminals located on the front panel.

13. The DMM of claim 12, further comprising a fuse holder accessible from the front panel.

14. The DMM of claim 9, further comprising a triaxial-to-banana adapter having a back panel configured for attachment to the upper, middle and lower triaxial terminals and a front panel having five banana terminals.

15. A adaptor configured to convert a front panel configuration of a PXIe form factor digital multimeter (DMM) device having less than five input terminals, the adapter comprising:
a back panel including rear terminals configured to connect to the corresponding input terminals of the DMM;
a front panel having five separate input terminals; and
an adaptor housing electrically connecting each of the input terminals of the front panel to a respective one of the rear terminals of the back panel.

16. The adaptor of claim 15, wherein the rear terminals of the back panel include three triaxial terminals.

17. The adaptor of claim 16, wherein each of the three triaxial terminals of the back panel include a center core wire, an inner conductor surrounding the center core wire, and an outer conductor.

18. The adaptor of claim 16, wherein the three triaxial terminals of the back panel include an upper triaxial terminal, a middle triaxial terminal, and a lower triaxial terminal,
wherein the center core wires of the upper, middle and lower triaxial terminals respectively constitute a high (HI) DMM terminal, a high sense (HIS) DMM terminal, and a current (I) DMM terminal, and
wherein inner conductors of the upper, middle and lower triaxial terminals respectively constitute a low (LO) DMM terminal, a low sense (LOS) DMM terminal, another DMM LO terminal.

19. The adaptor of claim 18, wherein the five separate terminals on the front panel includes:
an HI adaptor terminal electrically connected to the HI DMM terminal;
an LO adaptor terminal electrically connected to the LO DMM terminal;
an I adaptor terminal electrically connected to the I DMM terminal;
an HIS adaptor terminal electrically connected to the HIS DMM terminal; and
an LOS adaptor terminal electrically connected to the LOS DMM terminal.

20. The adaptor of claim 19, wherein each of the HI adaptor terminal, the LO adaptor terminal, the I adaptor terminal, the HIS adaptor terminal, and the LOS adaptor terminal is configured as a banana terminal.
